(19) United States
(12) Patent Application Publication
(10) Pub. No.: US 2009/0042433 A1
(43) Pub. Date: Feb. 12, 2009

(54) Data connector plug with internal cover and locking system

(76) Inventor: Donald P. Bushby, Houston, TX (US)

Correspondence Address: KENNETH A. RODDY, SUITE 100, 2916 WEST T.C. JESTER, HOUSTON, TX, 77018, US

(21) Appl. No.: 12/079,045

(22) Filed: Mar. 25, 2008

Related U.S. Application Data
(60) Provisional application No. 60/963,766, filed on Aug. 6, 2007.

(51) Int. Cl. H01R 13/627; H05K 7/00; H01R 13/64; H01R 13/648

(52) U.S. Cl. 439/352; 361/684; 439/680; 439/609

(57) ABSTRACT

Data connector plugs having an internal extensible and retractable cover and locking system and portable memory storage devices and data transfer cables equipped with the same have an internal extensible and retractable cover member which, in an extended and locked position, is disposed inside the case of the plug to at least partially occupy the void space adjacent to the metal contacts sufficient to physically prevent unauthorized connection with a mating connector and access and transfer of data and media, and in an unlocked retracted position exposes the electrical contacts to allow connection of the plug and electrical contacts with a mating connector for transferring data. The internal cover member may be sized to substantially fill the void space in a forward extended position to prevent damage to the contacts and ingress of dirt or debris.

### CROSS REFERENCE TO RELATED APPLICATION

This application claims priority of U.S. Provisional Patent Application Ser. No. 60/963,766, filed Aug. 6, 2007.

### BACKGROUND OF THE INVENTION

1. Field of the Invention

This invention relates generally to data connector plugs, serial bus connectors, and digital data security systems for memory storage devices, and more particularly to serial bus connectors and portable memory storage devices equipped with the same wherein the serial bus connector has an internal cover and locking system that can be locked to prevent connection of the connector to mating connectors, and thereby prevent unauthorized transfer of data and access to stored data and/or media, and may be coupled with a security cable to prevent theft of the memory storage device.

2. Background Art

As used herein, the term “portable memory storage device” refers to small portable devices having the capability to store large amounts of digital data and/or media, and are equipped with a data connector plug such as, for example, a Universal Serial Bus (USB) connector or Firewire® connector for uploading or downloading digital data and/or media between the memory device and a computer or other device. These portable memory storage devices are capable of storing data files, image files, music files, and video files. As used herein, the terms “other device”, “another device”, or “external device” refers to any device which is equipped with a mating connector such as, for example, a female Universal Serial Bus (USB) connector that receives the male connector plug for uploading or downloading digital data and/or media to or from a memory storage device.

Examples of portable memory storage devices include: “flash drives”, also known as “thumb drives”, “flash disks” or “pen drives”, “mini hard drives”, and portable audio players, portable video players, digital cameras, personal digital assistants (PDA), cell phones, and portable Firewire® corn patible devices.

These types of portable memory storage devices have increased dramatically in capability and popularity, while decreasing in size and expense. Due to their small size, these types of devices are also susceptible to theft or misplacement, and moreover, unauthorized use and/or downloading valuable files, digital data and/or media stored thereon by simply connecting the device to a computer or other device, without detection by the owner.

These devices commonly use Universal Serial Bus (USB) connectors. There are currently five different types of Universal Serial Bus (USB) male plug connectors in standard sizes, known as a “USB-A-M ale”, “USB-B-Male”, “Mini USB-A-Male” and “Mini USB-B-Male”. A Firewire® connector is an IEEE1394 compliant High Performance Serial Bus that provides two types of data transfer: asynchronous and isochronous, and is typically employed as an audio-visual connector. Asynchronous data transfer is for traditional load-and-store applications where data transfer can be initiated and an application interrupted as a given length of data arrives in a buffer. Isochronous data transfer ensures that data flows at a pre-set rate so that an application can handle it in a timed way while providing the bandwidth needed for audio, imaging, video, and other streaming data.

As used herein, the term “data connector plug” refers to as a digital data conducting plug having a case defining an open interior and an open end for interconnecting with a mating connector and a set of digital data conducting contacts disposed in the case. The term “serial bus connector plug” refers to a connector plug meeting serial bus interface standards for high-speed communications and asynchronous and isochronous real-time data transfer, for example a Universal Serial Bus (USB) connector or a Firewire® connector.

Most conventional portable memory storage devices of the type discussed above equipped with a male connector plug include a means for covering the plug to protect it from damage and prevent accumulation of dirt or debris. For example; simple covers or caps that slip over the end of the male connector plug, a pivotal cover or sheath that encloses the male plug when stored and allows it to pivot outward therefrom to expose the plug for use, and a retractable cover or sheath which allows the male connector plug to be retracted inside the sheath in a stored position and is extensible outwardly therefrom for use.

Wu, U.S. Pat. No. 6,522,534 discloses a pen-type portable memory device comprising a cartridge member including a chamber defined by a rigid wall for accommodating a memory unit and a detachable cap member, the chamber has an opening through which a USB plug or interface of the memory unit can extend, and the cap is detachably fitted with the chamber to close the opening and has an internal space for accommodating the USB plug or interface. The cap member can be disengaged from the chamber, permitting the USB plug to be directly plugged into a computer main frame.

Hsin-Hung Tu, U.S. Pat. No. 6,808,400 which is hereby incorporated herein by reference, is an example of a portable memory storage device with a connector plug which can be extended from and retracted into its housing.

These types of covers, caps and sheaths, and retractable plugs do not prevent unauthorized access to, and/or connection of the connector plug to external devices, nor prevent unauthorized access to the data and/or media stored in the device memory, nor prevent theft of the device. Another problem with conventional USB flash drives with extensible and retractable connector plugs or sheath covers is that the outer end of the connector is open or uncovered and is not covered or protected from the accumulation of debris, when either extended or retracted in to the sheath or housing. Another problem with portable memory storage devices having external caps or covers for the USB connector is that the cap or cover can be easily misplaced or lost.

There are several known devices for tethering or securing the portable memory device to a stationary object, such as a desk, workstation, or computer housing or case to prevent theft or misplacement of the memory device. A popular commercially available cable system is made by Kensington, of San Mateo, Calif. and described in U.S. Pat. No. 5,502,989. The cable is terminated at one end with a securing attachment to an anchor point on the valuable item and the other cable end is terminated with a locking device that attaches securely to the anchor point. The steel cable is arranged to loop around some large, preferably immovable object thus rendering the valuable item more difficult to steal.

Kung, U.S. Published Patent application 20040074264 discloses a portable data storage device, such as a pen drive or thumb drive, having a latching device that captures and traps a key-ring or security cable passing through the end opposite the USB plug that securely attaches the data storage device to deter theft of the storage device, without the need to unlock the security cable's lock.

While these types of tethering devices may be effective in preventing theft, removal, or misplacement of the memory device, they do not prevent unauthorized access to, and/or connection of the connector to external devices and thus, do not prevent theft the data and/or media stored in the device memory. An unauthorized person could still use and/or download valuable files, digital data and/or media stored on the memory device by simply connecting it to a laptop computer or other host device, without detection by the owner.

There are also several known methods employed for securing or preventing theft of the data or media stored on portable memory devices, which include: encryption, password protection, and biometric identification devices and methods. Although these methods are may be suitable for preventing unauthorized access to the data and/or media stored on the device, they do not prevent unauthorized connection of the connectors.

Lin, U.S. Published Patent application 20060004974 discloses a portable non-volatile memory device and method for preventing unauthorized access to data stored thereon without requiring self-installing software to protect the stored data. The device is activated when it is coupled to a computer and generates a window on the computer screen. A Graphical User Interface requests authentication information for accessing data stored on the device. If the correct authentication information is input, then access to the data stored on the device is granted; otherwise access to the data is denied.

Yen, U.S. Published Patent application 20060036872 discloses an anti-burglary USB flash drive with a press-button type electronic combination lock that adopts an IC password circuit without requiring a driver program for achieving the effects of preventing burglary and protecting confidential data stored in the USB flash drive by means of entering a password into a main body of the USB flash drive. A programmable logic IC in the main body of the USB flash drive checks the password, and if the password is correct, then the user is permitted to access the data stored in the USB flash drive.

Morikawa et al, U.S. Pat. Nos. 7,014,490 and 6,902,432 discloses a USB connector equipped with a latching or lock mechanism. The USB connector includes a receptacle having a shell and a receptacle terminal; a plug that includes a plug shell for fitting into the receptacle shell and a plug terminal; and an engagement release member that is provided on the plug shell so as to be movable between an engagement releasing position and an engagement position. When the plug is fitted into the receptacle, the plug terminal is electrically connected to the receptacle terminal. The plug shell has a retaining portion and the receptacle shell has an engagement portion, which is engaged with the retaining portion when the plug is fitted into the receptacle. The engagement release member maintains engagement of the retaining portion with the engagement portion in an engagement position, and the release member releases the engagement in an engagement releasing position.

Huetter et al, U.S. Pat. No. 6,619,976 discloses an apparatus and method for preventing inadvertent disconnection of male and female electrical connectors. In one embodiment, the devices are configured to provide outside retaining forces to retention prongs of a female electrical connector, substantially restricting or preventing the retention prongs from moving toward an outer non-holding position after connecting with receiving portions in the male connector. In another embodiment, the female electrical connector includes modified retention prongs having a portion configured to enter and remain in surface holes of the male connector so that the male connector, once inserted, cannot be removed from the female connector without a user manipulating the modified retention prongs.

Yu, U.S. Pat. No. 5,772,461 discloses a locking mechanism for interconnecting two mated connectors. A first receptacle connector includes a first main body having a first projecting section on the front portion, and a second plug connector includes a second main body having a second projecting section on the front portion wherein a hook device is provided on the first projecting section of the first receptacle connector and a locking slot is provided on the second projecting section of the second plug connector, and said second projecting section of the second plug connector further includes a release device which can incorporate the hook device of the first projecting section of the first receptacle connector to unhook the engagement between the hook of the first projecting section of the first receptacle and the locking slot of the second projecting section of the second plug connector.

Hirai, U.S. Pat. No. 5,634,809 discloses a connector with a lock mechanism having a connector main body in which are mounted electric contacts, a shield member for covering the connector main body and a connecting portion between the electric contacts and a cable, a casing for enclosing the connector main body and the shield member; and a lock mechanism for locking or unlocking a connection of the connector to a mating connector. The lock mechanism is made up of a flexible lock piece, one end of which is connected to the shield member; a pair of lock release slide plates which are slidable along upper and lower main surfaces of the casing; and slide members which slide inside the casing by sliding of the slide plates so as to release the locking by the lock piece.

Derstine et al, U.S. Pat. No. 5,435,744 discloses an overlying sliding boot assembly or cover for an electrical cable connector of the type that mates with and latchably engages a complementary connector. The connector includes a dielectric housing containing an array of electrical contacts for electrical engagement with respective contacts in a complementary connector. The connector further comprises a pair of unitary metal shielding members, a first one has a pair of latching arms extending from a mating end toward a cable receiving end, and a pair of hermaphroditic cover members formed of a dielectric material adapted to interfit together about the electrical connector in sliding engagement therewith, and movable from a first position to a second position to effect unmating of the electrical connector from the header assembly. Each cover member includes a latching arm receiving recess, and a flexible arm engageable with a complementary recess in the opposing cover member. Manual movement of the assembled cover members to the second position causes the respective flexible arms to flex from their released position. Releasing the assembled cover members effects a return of the assembled cover members to the first position.

The covers and locking arrangements of the aforesaid patents and published applications are lock mechanism that merely operate to lock or unlock the connector to a mating connector to hold them together and prevent accidental detachment. They do not prevent unauthorized access to and/or connection of the connector to an external device, nor prevent unauthorized access to the data and/or media stored on the device equipped with the mating connector.

Ales, U.S. Pat. No. 5,507,656 discloses an electrical plug lock that will temporarily disable the plug from being used to connect electrical equipment and devices to an electrical power outlet. The device consists of a relatively flat rectangular housing, a back panel and a cover. One end wall of the housing contains a pair of parallel slots adapted to receive the prongs of a conventional electrical plug. The housing is sufficiently thin that if the plug contained a third ground prong it would pass over the housing and not interfere with the operation of the lock. Within the housing is a U-shaped spring containing prong engaging nibs at the end of each arm. A spring biased plunger passes through the base of the flat spring and through the wall of the housing and disengages the nibs from the apertures in the prongs when depressed. Holes in the cover, plunger and the back panel are normally in alignment and permit the use of a conventional locking device to prevent the plunger from being depressed and the housing removed.

Richter, U.S. Pat. No. 5,601,440 discloses an electrical plug lock out apparatus comprising two matable, close-ended lids; a first female threaded lid and a second male threaded lid. Each lid has a flange or brim around the circumference of the lid which is integral with the lid. The flange or brim on each lid has an alignable hole for accepting a conventional padlock or similar device. The male threaded lid has a plurality of elongated “U” shaped slots running through the threaded wall of the lid to a point approximately midway through the non-threaded wall of the lid. Each slot is sized to accept an electrical cord having a plug head.

Vindigni, U.S. Pat. No. 5,944,550 discloses an electrical connection device lockable in an open position provided with a plug having a cylindrical body equipped with internal contact pins and a power transmitting female element in the form of a socket or a coupler socket of an extension cord, and having a casing equipped with internal contacts and an external rotational ring that projects by extending beyond the casing and intended to lock and unlock the plug from or into the connection position. The body of the plug is provided with a locking tab having an opening and the locking ring has an opening that get superposed during translational movement whereby the device can be locked by any means passing through the openings, such as a padlock.

Kameda, U.S. Pat. No. 6,733,311 discloses a connector with a shutter for protecting a contact portion of a peripheral device used in a computer. The connector comprises a housing, a shutter capable of closing an aperture portion of the housing, a spring for applying pressure to the shutter in the closed position and a stopper for detaining the shutter in the closed position. The housing accommodates the shutter, spring and stopper, and the shutter has a guiding device for guiding the shutter when it slides in opposition to the pressure of the spring.

Uchida, U.S. Pat. No. 7,086,880 discloses a miniature multi-polar electrical plug which can prevent the male contacts from being unprotected. The plug has a housing, male contacts, a shutter, a shell, and a pair of compressed coil springs. The plug housing has a header part and a frame part. The header part protrudes from the frame part and has a mounting board for mounting the male contacts and the shutter. The compressed coil springs move the shutter to cover or uncover the male contacts.

Ohta, et al, U.S. Pat. No. 7,125,269 discloses a connector provided with cover. An insulative connector body is accommodated in a conductive shield case. A conductive contact is provided on the connector body. An insulative cover is accommodated in the shield case so as to be slidable between a first position for concealing the contact and a second position for exposing a part of the contact and allowing a mating connector to electrically contact therewith. A conductive shield member is attached onto a front face of the cover which faces the mating connector. The shielding of the contacts by the cover is canceled in accordance with a connecting operation of the connector with respect to a mating plug, so that the contacts are prevented from electrostatic damage.

My previous patent, Bushby, U.S. Pat. No. 7,275,941, which is hereby incorporated herein by reference to the same extent as if fully set forth herein, discloses lockable portable memory storage devices equipped with male connector plugs and a locking system that prevents access to, and connection of the connector to external devices, and thereby prevents unauthorized use of the device and access to data and/or media stored thereon. The locking system may be incorporated in portable memory devices of the type having a cap or cover that fits over the end of the male plug, a connector plug that pivots relative to its cover or sheath, and devices having a connector plug that is extensible and retractable relative to its cover or sheath. The patented locking system allows an external locking device to be installed on the housing or sheath of the memory storage device, or between the housing and the cover, cap, or sheath that encloses or covers the connector to prevent exposure of the connector to an extent that would allow connection and use of the device.

My pending U.S. patent Ser. No. 11/504,494 (published application 20070037454), which is hereby incorporated herein by reference to the same extent as if fully set forth herein, discloses lock devices for installation on serial bus male connector plugs that prevents access to, and connection of the plug to other devices, such as memory storage devices. The lock devices have a housing with a receptacle which is installed onto the serial bus male connector plug to cover at least a portion of the male connector plug, and contain a locking mechanism and retaining member moveable between an unlocked position allowing disengagement and removal of the plug from the receptacle, and a locked position with plug securely engaged in the receptacle to prevent connection of the connector plug to a female serial bus connector of another device and unauthorized access to data stored in the memory of memory storage devices. The lock devices may have a shackle and a cap-holding tether attachment and may be utilized with conventional security cables and locking devices to also prevent theft of the memory storage device.

### SUMMARY OF THE INVENTION

The present invention overcomes the aforementioned problems and is distinguished over the prior art in general, and these patents in particular by a male data connector plug with an internal cover and locking system, and portable memory storage devices and data transfer cables equipped with the same wherein the male connector plug has an internal cover member extensible and retractable relative to the plug which, in an extended and locked position, is disposed inside the case of the plug to at least partially occupy the void space and cover the metal contacts to physically prevent unauthorized connection with a mating connector and access and transfer of data and media, and in an unlocked retracted position exposes the electrical contacts to allow connection of the plug and electrical contacts with a mating connector for transferring data, and when coupled with a security cable, also prevents theft of the memory storage device. The extensible and retractable cover member may be sized to cover and protect the electrical contacts from damage and accumulating dirt and debris in an extended position. The extensible and retractable cover member and/or the housing in which it is supported are provided with apertures that are aligned in the extended position to receive a conventional locking device such as a padlock, combination lock, cable lock, or security cable for locking the cover member in the extended position and when tethered to another object also prevents theft of the portable memory storage device. The cover member may be manually moved between the retracted and extended position by a thumb slide, urged into a normally extended portion by resilient spring means, or may be moved between the retracted and extended position by electromechanical means.

Another aspect of the present invention is the provision of methods for preventing connection of a data connector plug with a mating connector of another device, and preventing unauthorized access to and transfer of stored data and media.

There has thus been outlined, rather broadly, the more important features of the invention in order that the detailed description thereof may be better understood, and in order that the present contribution to the art may be better appreciated. There are additional objects, features and advantages of the invention that will be described hereinafter.

A primary object of the present invention is to provide a male data connector plug having an internal extensible and retractable cover member and locking system that will overcome the shortcomings of the prior art devices.

Another object of the present invention is to provide a portable memory storage device having a male data connector plug with an internal extensible and retractable cover member and locking system wherein the cover member may be locked in the extended position to prevent connection of the connector to a mating connector of another device, and, thereby prevent unauthorized access to and transfer of stored data and media.

A further object of the present invention is to provide a data communication cable having a male data connector plug with an internal extensible and retractable cover member and locking system wherein the cover member may be locked in the extended position to prevent connection of the connector to a mating connector of another device, and, thereby prevent unauthorized access to and transfer of stored data and media.

A still further object of the present invention is to provide methods for preventing connection of a data connector plug with a mating connector of another device, and preventing unauthorized access to and transfer of stored data and media.

One of the features and advantages of the present male data connector plug with internal extensible and retractable cover member and locking system is that the internal cover at least partially fills the connector plug housing in an extended position and can be locked in the extended position to prevent connection of the connector to a mating connector of another device, and, thereby prevent unauthorized access to and transfer of stored data and media.

Another feature and advantage of the present male data connector plug with internal extensible and retractable cover member and locking system is that the internal cover member, in an extended position, covers the electrical contacts of the serial bus connector plug to protect the contacts from damage and prevent accumulation of dirt and debris.

Another feature and advantage of the present male data connector plug with internal extensible and retractable cover member and locking system, and portable memory storage devices equipped with the same, is that the cover member may be locked in the extended position by the shackle of a conventional lock device or a security cable which can be securely anchored to another object, or connected to any suitable object, such as a briefcase, computer bag, handbag, etc., in order to prevent the unauthorized removal or theft of the connector plug or memory storage device.

A further feature and advantage of the present male data connector plug with internal extensible and retractable cover member and locking system is that the cover member is housed within the plug housing and protected by the housing and, thus, is tamper resistance and will not become lost or misplaced.

A still further feature and advantage of the present invention is that portable memory storage devices and data communication cables having the male data connector plug with internal extensible and retractable cover member and locking system may be packaged along with a locking device and sold together for the convenience of the consumer.

Other objects, features and advantages of the invention will become apparent from time to time throughout the specification and claims as hereinafter related.

### BRIEF DESCRIPTION OF THE DRAWINGS

The novel features believed to be characteristic of the invention are set forth in the appended claims. The present invention itself, however, as well as a preferred mode of use, further objectives, features and advantages thereof, will best be understood by reference to the following detailed description of preferred embodiments when read in conjunction with the accompanying drawings, in which like reference characters designate the same or similar parts throughout the several views.

FIG. 1 is an isometric view of a conventional prior art portable memory storage device of the type having a removable cap for covering the Universal Serial Bus (USB) male connector plug.

FIGS. 2A and 2B are isometric views of a conventional prior art portable memory storage device of the type having a retractable Universal Serial Bus (USB) male connector plug, shown in the retracted and extended positions, respectively.

FIG. 3 is an isometric view of a conventional prior art data transfer cable having a Universal Serial Bus (USB) male connector plug.

FIG. 4 is an enlarged isometric view a conventional Universal Serial Bus (USB) male connector plug with the housing shown in dashed line.

FIGS. 5A and 5B are enlarged isometric views of a male data connector plug with an internal cover and locking system in accordance with the present invention in the form of a Universal Serial Bus (USB) male connector plug shown with a portion of the housing in dashed line and showing the internal cover member somewhat schematically in a retracted and extended position, respectively.

FIGS. 6A and 6B are isometric views of a portable memory storage device having a Universal Serial Bus (USB) male connector plug with an internal cover in accordance with the present invention, shown with the internal cover member in the retracted and extended positions, respectively.

FIG. 7A is a longitudinal cross section taken along line 7A-7A of FIG. 5A, showing the internal cover member in the retracted position.

FIG. 7B is a longitudinal cross section taken along line 7B-7B of FIG. 5B, showing the internal cover member in the extended position with a locking member extending through the aligned holes.

FIG. 8 is a perspective view of a conventional padlock, and a cable lock, which may be used to lock the internal cover member in the extended position.

FIG. 9 is an isometric view of a portable memory storage device having a Universal Serial Bus (USB) male connector plug with an internal cover in accordance with the present invention, shown with the internal cover member locked in an extended position by a locking device.

FIG. 10 is an isometric views of a data transfer cable having a Universal Serial Bus (USB) male connector plug with an internal cover in accordance with the present invention, shown with the internal cover member locked in an extended position by a locking device.

### DESCRIPTION OF THE PREFERRED EMBODIMENTS

Detailed descriptions of the preferred embodiments are provided herein. It is to be understood, however, that the present invention may be embodied in various forms. Therefore, specific details disclosed herein are not to be interpreted as limiting, but rather as a basis for the claims and as a representative basis for teaching one skilled in the art to employ the present invention in virtually any appropriately detailed system, structure or manner.

The male data connector plug depicted in the drawing figures is shown and described, for purposes of example only, as a Universal Serial Bus (USB) male connector plug, and it should be understood that the data connector plug may be of any type that has a case and is capable of being connected to a mating connector of another device which may be interconnected with the memory storage member of a memory storage device for accessing and transferring digital data. The connector plug may be located on a memory storage device or at one end of a data transfer cable connected with a memory storage device, or devices that may or may not contain memory, such as a keyboard, card reader, USB hub, etc.

It should also be understood that the interior components of the serial bus connector plugs and memory storage devices described herein, and the electronic circuitry are of standard conventional construction and well known in the art, and therefore, are represented somewhat schematically and not shown or described in detail.

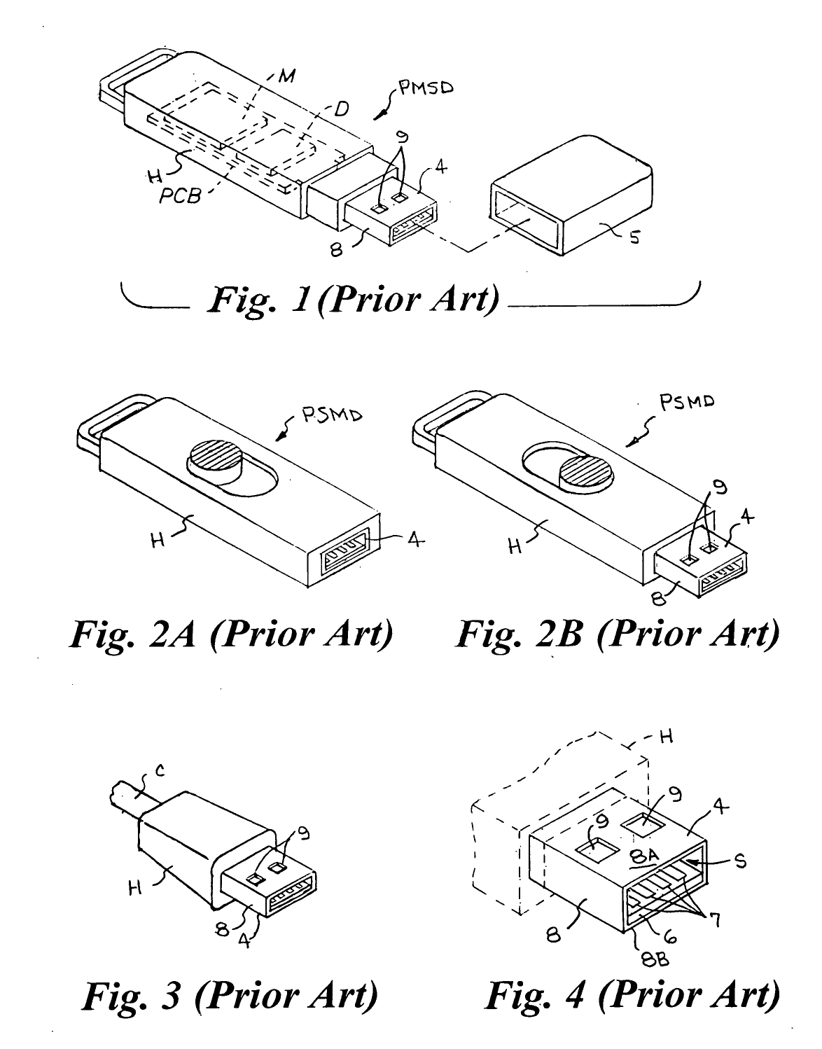

Referring now to the drawings by numerals of reference, there is shown in FIGS. 1, 2 and 3, an example of a conventional prior art portable memory storage device PMSD having a fixed Universal Serial Bus (USB) male connector plug 4 with a removable cap 5 for covering the plug, a conventional prior art portable memory storage device PMSD having a retractable Universal Serial Bus (USB) male connector plug 4, and a conventional prior art data transfer cable C having a Universal Serial Bus (USB) male connector plug 4, respectively.

As best seen in FIG. 1, the conventional portable memory storage device PMSD has a main body or housing H in which is housed one or more printed circuit boards PCB, which include a memory storage means M such as a memory IC (integrated circuit) or a memory chip or disk, a controller or driver D, and a standard serial bus male connector plug 4, for example, a USB (Universal Serial Bus) connector plug at one end. The male connector plug 4 may be mounted or connected at one end with the PCB, and a part of the plug protrudes through an opening at one end of the body or housing H, or is movable relative thereto as shown in FIG. 2, to be inserted into a mating female socket or port on an external device, such as a computer or other device for transferring digital data between the memory storage and external device. In the case of a data transfer cable C (FIG.3), the male serial bus connector 4 is located at one end of the cable, which has another end connected with the memory storage of a memory storage device (not shown).

It should be understood that the portable memory device PMSD is illustrated for purposes of example only, and that the memory storage device may be any type of portable or non-portable memory storage device which is equipped with a serial bus connector plug, such as desktop or laptop computer hard drive, an external hard drive, or a data transfer cable connectable or connected to a memory storage device, and the connecter plug may be located on devices that may or may not contain memory, such as a keyboard, card reader, USB hub, etc.

It should also be understood that serial bus connector plug is depicted herein as a Universal Serial Bus (USB) male connector plug, for purposes of example only, and may be any standard serial bus connector plug meeting serial bus interface standards for high-speed communications and asynchronous and isochronous real-time data transfer, for example a “USB-A-Male”, “USB-B-Male”, “Mini USB-A-Male” or “Mini USB-B-Male” or a Firewire® connector. It is well understood to those skilled in the art, that the size and shape and standards of digital data transfer connectors will change as new connectors are developed. Thus, the present invention is not limited to only USB connectors, or those connectors currently available.

Referring now to FIG. 4, a conventional Universal Serial Bus (USB) male connector plug 4 is shown at a larger scale. The principal mechanical and electrical characteristics of these connectors are standardized according to a convention well known in the art. The male connector plug 4 contains a small connector substrate 6, which is often white ceramic, black rigid plastic, or other sturdy substrate, which has a four or more metal contacts 7 formed thereon that carry the USB data signals generated or received by the controller or driver chip D. The USB connector plug 4 also has a metal case 8 that wraps around connector substrate 6 and has top and bottom surfaces 8A and 8B, each having a pair of apertures 9, typically rectangular holes therethrough, which become aligned with detents of the retention prongs of the USB female connector (conventional and therefore not shown) when the male connector plug is fully inserted into the female connector. Typically, there is a relatively large gap or space S between the top side of the connector substrate 6 holding the metal contacts 7 and the top surface 8A of the metal case 8 to accommodate mating metal contacts found in the female connector.

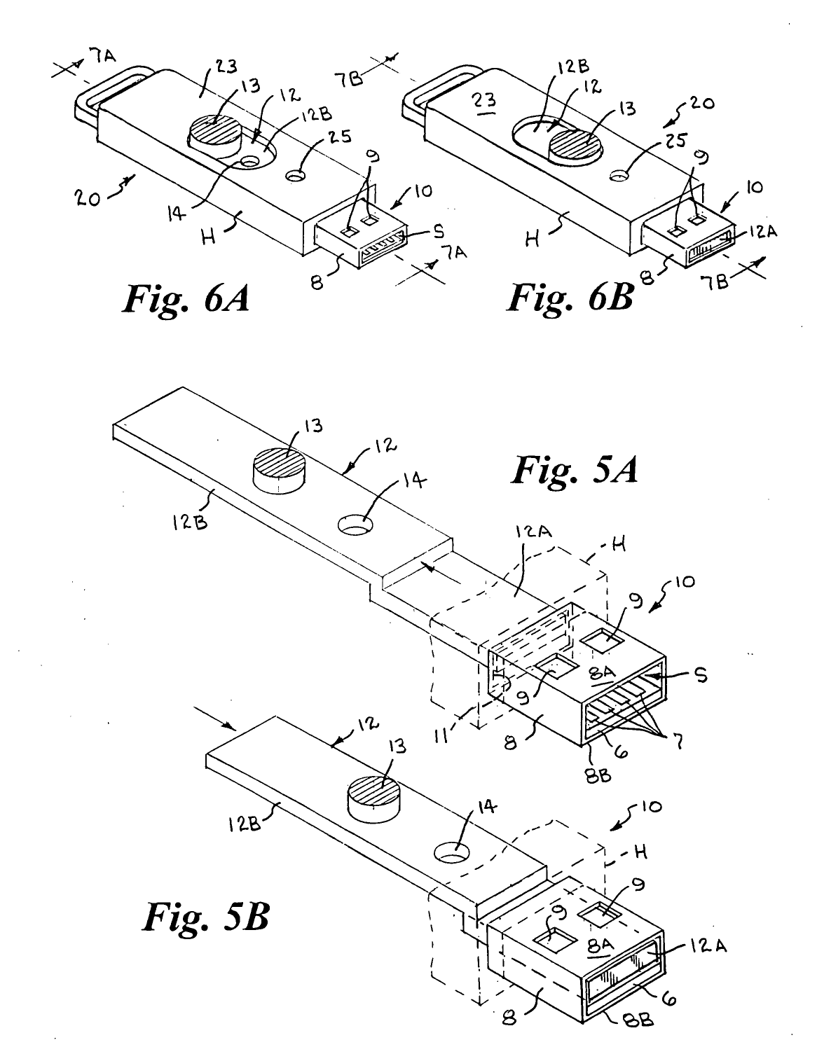

FIGS. 5A and 5B illustrate, somewhat schematically, the major components of the male data connector plug 10 in accordance with the present invention, which incorporates an internal extensible and retractable cover member 12 that can be moved between a retracted and extended position. The male connector plug 10 is depicted as a Universal Serial Bus (USB) male connector plug, for purposes of example only, and it should be understood that the present data connector plug may be any serial bus connector plug meeting serial bus interface standards for high-speed communications and asynchronous and isochronous real-time data transfer, for example a “USB- A-Male”, “USB-B-Male”, “Mini USB-A-Male” or “Mini USB-B-Male” or a Firewire® connector, modified as set forth herein. It is well understood to those skilled in the art, that the size and shape and standards of digital data transfer connectors will change as new connectors are developed. Thus, the present invention is not limited to only USB connectors, or those connectors currently available.

As with the conventional USB male connector plug described above, the present serial bus male connector plug 10 contains a small connector substrate 6 having metal contacts 7 formed thereon that carry digital data, a metal case 8 that wraps around the connector substrate having top and bottom surfaces 8A and 8B, and may have a pair of apertures 9 that become aligned with detents of the retention prongs of a mating female connector (conventional and therefore not shown) when the male connector plug is fully inserted into the female connector. A relatively large gap or space S is defined between the top side of the connector substrate 6 holding the metal contacts 7 and the top surface 8A of the metal case 8 to accommodate mating metal contacts found in the female connector. The case 8 of the present serial bus male connector plug 10 is provided with a slot or opening 11 at its back end.

In the illustrated example, the internal extensible and retractable cover member 12 is a generally rectangular plate formed of a rigid preferably electrically non-conductive material, which is mounted rearwardly of the male serial bus connector plug 10 to move relative thereto between a rearward retracted position and a forward extended position, as described hereinafter. The sliding plate member 12 has a front end portion 12A that is sized and shaped to extend through the slot or opening 11 at the back end of the metal case 8 that wraps around the connector substrate 6 and a sufficient distance into the void gap or space S between the top side of the connector substrate 6 holding the metal contacts 7 and the top surface 8A of the metal case so as to at least partially occupy the space and cover the metal contacts. The cover member 12 has a rear end portion 12B that is provided with an operator mechanism, such as a push button or thumb slide 13 for moving it between the retracted and extended positions, and an aperture or hole 14 extending therethrough for receiving a locking device for securing it in the extended position, as described hereinafter.

In the rearward retracted position (FIG. 5A), the front end portion 12A of the cover member 12 exposes the metal contacts 7 to allow the male serial bus connector plug 10 to be fully inserted into a mating female connector receptacle (not shown) and mating of the contacts 7 with the contacts of the female connector to establish data communication.

In the extended position (FIG. 5B), the front end portion 12A of the cover member 12 occupies the void gap or space S between the top side of the connector substrate 6 holding the metal contacts 7 and the top surface 8A of the metal case 8 and at least partially covers the metal contacts to prevent the male serial bus connector plug 10 from being inserted into a mating female connector and mating of the contacts 7 with the contacts of a female connector, thereby preventing connection to and data communication with and external device. The front end portion 12A of the sliding cover member 12 may be sized and shaped to substantially fill the space S between the contacts 7 and inside surface of the metal case 8 or may be somewhat smaller. The extensible and retractable cover member 12 may also be sized to substantially fill the space S and cover the contacts 7 in a forward extended position to prevent damage to the contacts and ingress of dirt or debris.

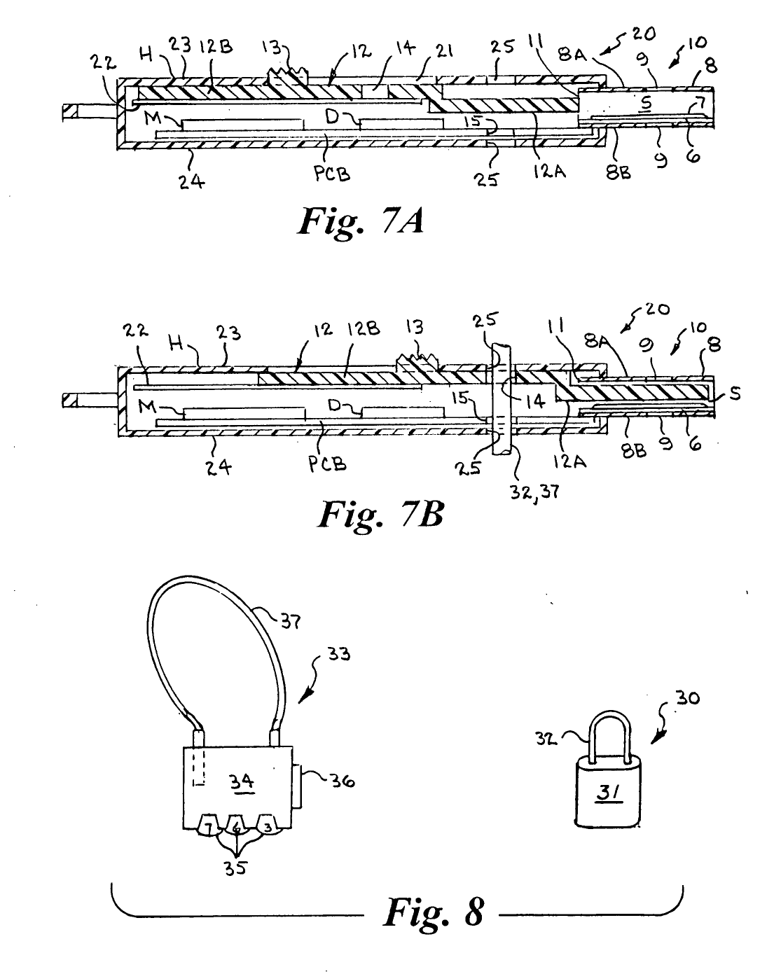

Referring now to FIGS. 6A, 6B, 7A, and 7B, there is shown a portable memory storage device 20 having a fixed serial bus male connector plug 10, as described above, shown with the internal cover member 12 locked in an extended position by a locking device 30. In this arrangement, the portable memory storage device PMSD 20 has a main body or housing H in which is housed one or more printed circuit boards PCB, which include a memory storage means M such as an integrated circuit (IC) memory chip or disk, a controller or driver D, and the serial bus male connector plug 10 is mounted or connected at one end with the circuit board with its contacts 7 connected with the circuitry for communication with the memory storage means. A front part of the serial bus male connector plug 10 protrudes through an opening at one end of the body or housing H. The printed circuit board PCB is provided with an aperture or hole 15 extending therethrough for receiving a locking device, as described hereinafter. The hole 15 in the printed circuit board PCB is positioned so as not to interfere with any of the electronic circuitry.

The top side of the housing H is provided with a slot 21 through which the push button or thumb slide 13 of the internal cover member 12 protrudes. It should be understood that, alternatively, one or both lateral sides of the internal cover member 12 may be provided with a push button or thumb slide 13 and one or both lateral sides of the housing H may be provided with a slot 21 through which the push button or thumb slide 13 protrudes.

The internal cover member 12 is slidably supported in the body or housing H of the portable memory storage device 20 above the printed circuit board PCB, memory storage means M and controller or driver D. The laterally opposed side walls of the body or housing H of the portable memory storage device PMSD may be provided with laterally opposed ledges 22 on which the rear portion 12B of the internal cover member 12 is slidably supported. Alternatively, both lateral sides of the rear portion 12B of the internal cover member 12 may be provided with a push button or thumb slide 13 and the lateral sides of the housing H may be provided with a slot 21 through which the push buttons or thumb slides 13 protrude such that the internal cover member 12 is slidably supported in the slots 21 by the protruding push buttons or thumb slides 13.

The top wall 23 and bottom wall 24 of the body or housing H of the portable memory storage device 20 each have an aperture or hole 25 extending therethrough in axial alignment with the hole 15 in the printed circuit board PCB. When the internal cover member 12 is in the fully extended position, the hole 14 in its rear portion 12B is aligned with the hole 15 in the printed circuit board PCB and the holes 25 in the bottom wall 23 of the housing H of the portable memory storage device 20.

Referring additionally to FIG. 8, there is shown a conventional padlock 30 having a case 31 and U-shaped metal shackle 32, and a cable lock 33 having a case 34 with rotatable code number dials 35, a release button 36, and a flexible cable 37, either of which may be used to lock the internal cover 12 in the extended position. The padlock 30 and cable lock 33 are conventional and well known in the art, and therefore not shown or described in detail. It should be understood that either of the locks may have a key type or combination type or other type of opening mechanism.

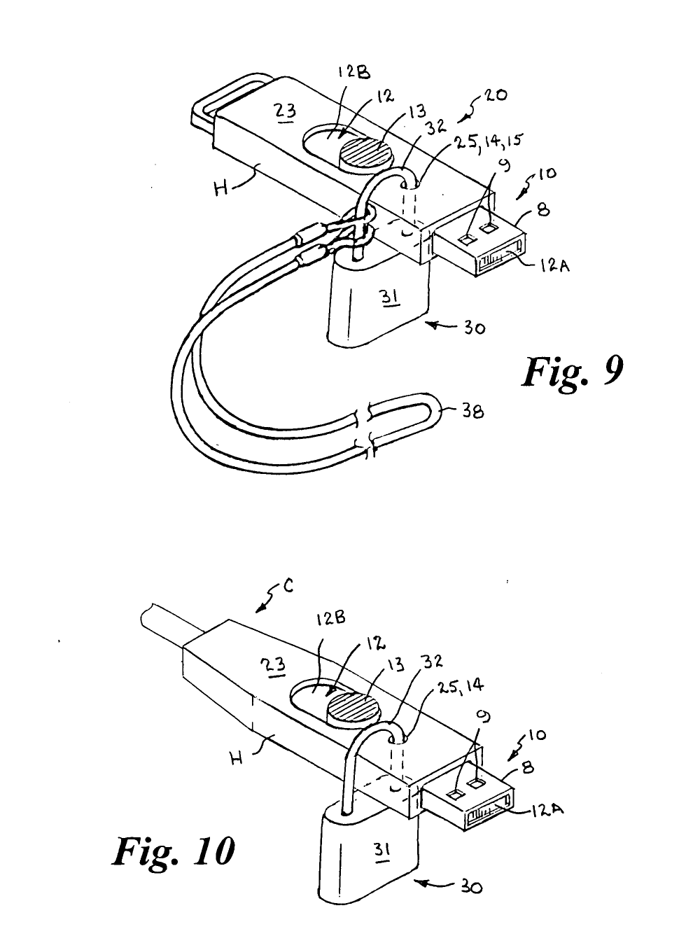

As shown in FIGS. 7B and FIG. 9, when the internal cover member 12 is in the fully extended position, a locking device, such the shackle 32 of a padlock 30, or the cable 37 of a cable lock 33 (FIG. 8) is installed through the aligned holes 25, 14, and 15 in the housing H, cover member 12, and printed circuit board PCB to prevent the internal cover member from being retracted to expose the contacts 7 of the plug 12 and prevent unauthorized connection of the plug and, thus, prevent connection of the connector plug to an external device and unauthorized access to data and media stored in the memory. It should be understood that a conventional security cable 38 may be coupled to the shackle or cable of the lock, whereby the memory device secured by the lock in its locked condition can also be secured to another object, such as a computer, desk, briefcase, purse, etc., to prevent theft of the portable memory storage device 20.

Alternatively, the hole in the top wall of the housing H of the portable memory storage device 20 may be eliminated and the holes 14 and 15 in the cover member 12 and PCB located rearward of the push button or thumb slide 13 of the internal cover member 12. In this modification, the shackle 32 or the cable lock cable 37 is installed through the slot 21 in the housing H and the aligned holes 14, 15 and the hole 25 in the bottom wall of the housing to prevent the internal cover member 12 from being retracted to expose the contacts 7 of the plug 12 and prevent unauthorized connection of the plug.

It should also be understood that, alternatively, the internal cover member 12 may be sized such in the fully extended position the back end of its rear portion 12B is disposed a short distance forward of the back end of the slot 21 to define a small opening therebetween, whereby the shackle of the padlock, or the cable lock cable can be installed through the opening and the aligned holes in the PCB and the bottom of the housing to lock the internal cover member in its fully extended position, in which case the hole 14 in its rear portion could be eliminated.

Referring now to FIG. 10 there is shown a data transfer cable C having a serial bus male connector plug 10 in accordance with the present invention, shown with the internal cover member 12 locked in the extended position by a locking device, such as the shackle 32 of a padlock 30. The components previously shown and described are assigned the same numerals of reference, but will not be described again in detail here to avoid repetition. In this arrangement, the serial bus male connector plug 10 is disposed on the plug body or plug housing PH of a plug 40 at the at one end of the data transfer cable C, which has its other end connected with a memory storage device, or a device that may or may not contain memory, such as a keyboard, card reader, USB hub, etc.

In this example, the plug body or plug housing PH of the plug 40 at the one end of the cable C does not contain a printed circuit board, memory storage means, or a controller or driver D. Instead, the contacts 7 are connected by leads extending through the cable which are connected with the circuitry of the memory storage device, in a manner which is well known in the art, and therefore not shown. The front part of the serial bus male connector plug 10 protrudes from one end of the plug body or plug housing PH and the plug body or plug housing has an interior cavity rearward of the serial bus male connector plug 10 to accommodate the cover member 12.

As with the portable memory storage device described previously, the top side of the plug housing PH is provided with a slot 21 through which the push button or thumb slide 13 of the internal cover member 12 protrudes, and two opposed walls of the plug housing OH are provided with aligned holes 25. The internal cover member 12 is slidably supported in the interior cavity of the plug housing PH. The laterally opposed side walls of the interior cavity of the plug housing PH may be provided with laterally opposed ledges on which the rear portion 12B of the internal cover member 12 is slidably supported. Alternatively, both lateral sides of the rear portion 12B of the internal cover member 12 may be provided with a push button or thumb slide and each of the lateral sides of the plug housing PH and cavity may be provided with a slot through which the push buttons or thumb slides protrude such that the internal cover member 12 is slidably supported in the slots 21 by the protruding push buttons or thumb slides 13.

When the internal cover member 12 is in the fully extended position, the shackle 32 of a padlock 30, or the cable 37 of a cable lock 33 (FIG. 3) is installed through the slot 21 in the plug housing PH and the aligned holes 14 and 23 to prevent the internal cover member from being retracted to expose the contacts 7 of the plug 12 and prevent unauthorized connection of the plug.

Also, as described previously, Alternatively, the top wall of the plug housing PH may eliminated and the cover member 12 provided with an aperture or hole rearwardly rearward of the push button or thumb slide 13 of the internal cover member 12 for receiving the shackle through the slot 21 in the housing PH and aligned holes in the cover member 12 and one wall of the housing to prevent the internal cover member 12 from being retracted. It should also be understood that, alternatively, the hole in the internal cover member 12 may be eliminated and the cover member sized such in the fully extended position the back end of its rear portion 12B is disposed a short distance forward of the back end of the slot 21 to define a small opening therebetween, whereby the shackle of the padlock, or the cable lock cable can be installed through the opening and the hole in one wall of the housing to lock the internal cover member in its fully extended position.

Although the preferred embodiments have shown and described the internal cover member 12 as being manually moved between the retracted and extended positions, it should be understood that it may be urged into a normally extended portion by resilient spring means, or may be moved between the retracted and extended position by electromechanical means.

It should also be understood that the cover portion of the extensible and retractable cover member 12 may be sized to substantially fill the space between the contacts 7 and interior surface of the case 8 so as to cover to cover the contacts 7 in a forward extended position and may be used to protect the contacts from damage and prevent ingress of dirt or debris, with or without a locking device. It should also be understood that the extensible and retractable cover member may be provided without holes and the holes in the printed circuit board PCB and the housing in which it is supported eliminated such that the retractable cover member serves as an internal cover to protect the electrical contacts of the male data connector plug 10 from damage and accumulating dirt and debris.

The foregoing disclosure and description of the invention is illustrative and explanatory thereof. Various changes in the details of the illustrated construction and methods may be made within the scope of the appended claims without departing from the spirit of the invention. No limitations are intended to the details of construction or design, herein shown, or to the methods described herein, other than are described in the claims below. The present invention should only be limited by the following claims and their legal equivalents.

1. A selectively lockable digital data conducting connector plug connectable to a mating connector for conducting digital data, comprising:
a digital data conducting connector plug having a case defining an open interior and an open front end for interconnecting with a mating connector, a set of digital data conducting contacts disposed in said case, a space between an inner facing surface of said case and said contacts for receiving a set of mating digital data conducting contacts disposed in the mating connector when said connector plug is connected therewith, and an opening at a back end of said case;
an extensible and retractable lockable member having a cover portion sized and shaped to extend through said opening a sufficient distance to at least partially occupy said space and cover said contacts in a forward extended position and to open said space and expose said contacts in a rearward retracted position; and
locking means associated with said lockable member for selectively locking said lockable member in said forward extended position; whereby
in said rearward retracted position, said lockable member cover portion opens said space and exposes said set of contacts to allow connection of said connector plug with said mating connector and engagement of said contacts with the mating digital data conducting contacts for establishing digital data communication; and
in said forward extended and locked position, said lockable member cover portion prevents connection of said connector plug with said mating connector and engagement of said contacts with the mating digital data conducting contacts to prevent establishing digital data communication.

2. The selectively lockable connector plug according to claim 1, wherein
said connector plug comprises a serial bus male connector plug, and said case is a generally rectangular case.

3. The selectively lockable connector plug according to claim 1, further comprising:
moving means connected with said lockable member for moving said lockable member between said rearward retracted position and said forward extended position.

4. The selectively lockable connector plug according to claim 3, wherein
said moving means comprises at least one push button connected with said lockable member for manually moving said lockable member between said rearward retracted position and said forward extended position.

5. The selectively lockable connector plug according to claim 1, wherein
said extensible and retractable lockable member comprises a generally flat rectangular member having a front end portion defining said cover portion.

6. The selectively lockable connector plug according to claim 1, further comprising:
a housing surrounding said case back end, and said case protruding outwardly from said housing.

7. The selectively lockable connector plug according to claim 6, wherein:
said extensible and retractable lockable member comprises a generally flat rectangular member having a front end portion defining said cover portion, and a generally flat rectangular rear portion slidably mounted in said housing.

8. The selectively lockable connector plug according to claim 7, wherein
said locking means comprises lock receiving means on at least one of said housing and said lockable member for receiving a locking device to secure said lockable member in said forward extended position.

9. The selectively lockable connector plug according to claim 8, wherein
said lock receiving means comprises at least one aperture extending through at least one of said housing and said lockable member in a position to become axially aligned when said lockable member is in said forward extended position for receiving either of a shackle or cable of a lock device, or a lockable security cable, therethrough to prevent unauthorized movement of said lockable member to said rearward retracted position.

10. The selectively lockable connector plug according to claim 1, wherein
said digital data conducting connector plug is disposed on a portable memory storage device.

11. The selectively lockable connector plug according to claim 6, wherein
said digital data conducting connector plug is disposed at an end of a data transfer cable.

12. A memory storage device having a lockable digital data conducting connector plug connectable to a mating connector for conducting digital data, comprising:
a memory storage device having a housing, memory storage means in said housing for storing digital data, and a digital data connector plug protruding from said housing adapted to be connected with mating connector of an external device for accessing and transferring digital data between the memory storage means and the external device;
said connector plug having a case defining an open interior and an open front end for interconnecting with a mating connector, a set of digital data conducting contacts disposed in said case interconnected with said memory storage means, a space between an inner facing surface of said case and said contacts for receiving a set of mating digital data conducting contacts disposed in the mating connector when said connector plug is connected therewith, and an opening at a back end of said case;
an extensible and retractable lockable member having a cover portion sized and shaped to extend through said opening a sufficient distance to at least partially occupy said space and cover said contacts in a forward extended position and to open said space and expose said contacts in a rearward retracted position; and
locking means associated with said lockable member for selectively locking said lockable member in said forward extended position; whereby
in said rearward retracted position, said lockable member cover portion opens said space and exposes said set of contacts to allow connection of said connector plug with the mating connector and engagement of said contacts with the mating digital data conducting contacts for establishing digital data communication; and
in said forward extended and locked position, said lockable member cover portion prevents connection of said connector plug with the mating connector and engagement of said contacts with the mating digital data conducting contacts to prevent establishing digital data communication.

13. The memory storage device according to claim 12, wherein
said connector plug comprises a serial bus male connector plug, and said case is a generally rectangular case.

14. The memory storage device according to claim 12, further comprising:
moving means connected with said lockable member for moving said lockable member between said rearward retracted position and said forward extended position.

15. The memory storage device according to claim 14, wherein
said moving means comprises at least one push button connected with said lockable member for manually moving said lockable member between said rearward retracted position and said forward extended position.

16. The memory storage device according to claim 12, wherein
said extensible and retractable lockable member comprises a generally flat rectangular member having a front end portion defining said cover portion, and a generally flat rectangular rear portion slidably mounted in said housing.

17. The memory storage device according to claim 16, wherein
said locking means comprises lock receiving means on at least one of said housing and said lockable member for receiving a locking device to secure said lockable member in said forward extended position.

18. The memory storage device according to claim 17, wherein
said lock receiving means comprises at least one aperture extending through at least one of said housing and said lockable member in a position to become axially aligned when said lockable member is in said forward extended position for receiving either of a shackle or cable of a lock device, or a lockable security cable, therethrough to prevent unauthorized movement of said lockable member to said rearward retracted position.

19. The memory storage device according to claim 12, wherein
said memory storage device is a portable memory storage device.

20. The memory storage device according to claim 12, wherein
said extensible and retractable lockable member cover portion is sized and shaped to at least partially occupy said space and cover said contacts in a forward extended position sufficient to protect said contacts from damage and prevent ingress of dirt or debris.

21. A portable memory storage device with a digital data conducting connector plug and internal cover therefor, comprising:
a portable memory storage device having a digital data conducting connector plug, said plug having a case defining an open interior and an open front end for interconnecting with a mating connector, a set of digital data conducting contacts disposed in said case, a space between an inner facing surface of said case and said contacts, and an opening at a back end of said case; and
an extensible and retractable cover member sized and shaped to extend through said opening and into said space to at least partially occupy said space and cover said contacts in a forward extended position sufficient to prevent ingress of dirt or debris into said space, and to open said space and expose said contacts in a rearward retracted position sufficient to allow connection of said plug with a mating connector.

22. The portable memory storage device according to claim 21, wherein
said connector plug comprises a serial bus male connector plug, and said case is a generally rectangular case.

23. The portable memory storage device according to claim 21, wherein
said extensible and retractable cover member comprises a generally flat rectangular member.

24. The portable memory storage device according to claim 21, further comprising:
moving means connected with said extensible and retractable cover member for moving said cover member between said rearward retracted position and said forward extended position.

25. The portable memory storage device according to claim 24, wherein
said moving means comprises at least one push button connected with said cover member for manually moving said cover member between said rearward retracted position and said forward extended position.

26. The portable memory storage device according to claim 21, further comprising:
locking means associated with said extensible and retractable cover member for selectively locking said cover member in said forward extended position to prevent connection of said plug with a mating connector.

27. The portable memory storage device according to claim 26, wherein
said locking means comprises lock receiving means on at least one of said portable memory storage device and said cover member for receiving a locking device to secure said cover member in said forward extended position.

28. The portable memory storage device according to claim 21, wherein
said connector plug comprises a USB type A connector plug, and said portable memory storage device is selected from the group consisting of flash drives, thumb drives, flash disks, pen drives, mini hard drives, portable audio players, portable video players, digital cameras, personal digital assistants, cell phones, and portable memory storage devices having a USB type A connector plug.

29. A method for preventing connection of a digital data conducting connector plug to a mating connector, comprising the steps of:
providing a digital data conducting connector plug having a case defining an open interior and an open front end for interconnecting with a mating connector, a set of digital data conducting contacts disposed in said case, a space between an inner facing surface of said case and said contacts for receiving a set of mating digital data conducting contacts disposed in the mating connector when said connector plug is connected therewith, and an opening at a back end of said case;
providing an extensible and retractable lockable member having a cover portion sized and shaped to extend through said opening a sufficient distance to at least partially occupy said space and cover said contacts in a forward extended position and to open said space and expose said contacts in a rearward retracted position; and
moving said lockable member to said forward extended position, and locking said lockable member in said forward extended position to prevent connection of connector plug with said mating connector and engagement of said contacts with the mating digital data conducting contacts to prevent establishing digital data communication; and
unlocking and moving said lockable member to said rearward retracted position to open said space and expose said contacts to allow connection of said connector plug with the mating connector and engagement of said contacts with the to establishing digital data communication.

30. A method for preventing unauthorized access to digital data and/or media files stored in the memory of a memory storage device, comprising the steps of:
providing a digital data conducting connector plug having a case defining an open interior and an open front end for interconnecting with a mating connector, a set of digital data conducting contacts disposed in said case, a space between an inner facing surface of said case and said contacts for receiving a set of mating digital data conducting contacts disposed in the mating connector when said connector plug is connected therewith, and an opening at a back end of said case, at least one of said sets of digital data conducting contacts being interconnected with the memory of a memory storage device;
providing an extensible and retractable lockable member having a cover portion sized and shaped to extend through said opening a sufficient distance to at least partially occupy said space and cover said contacts in a forward extended position and to open said space and expose said contacts in a rearward retracted position; and
moving said lockable member to said forward extended position, and locking said lockable member in said forward extended position to prevent connection of connector plug with said mating connector and engagement of said contacts with the mating digital data conducting contacts to prevent establishing digital data communication and unauthorized access to data stored in the memory of the memory storage device; and
unlocking and moving said lockable member to said rearward retracted position to open said space and expose said contacts to allow connection of said connector plug with said mating connector and engagement of said contacts with the mating contacts of the mating connector to allow authorized access to data stored in the memory of the memory storage device.

31. A method for covering contacts of a digital data conducting connector plug of a portable memory storage device, comprising the steps of:
providing a portable memory storage device with a digital data conducting connector plug having a case defining an open interior and an open front end for interconnecting with a mating connector, a set of digital data conducting contacts disposed in said case, a space between an inner facing surface of said case and said contacts, and an opening at a back end of said case;
providing an extensible and retractable cover member sized and shaped to extend through said opening and into said space;
extending said cover member forwardly of said opening to at least partially occupy said space and cover said contacts sufficient to protect said contacts from damage and prevent ingress of dirt or debris into said space; and
retracting said cover member rearwardly to open said space and expose said contacts sufficient to allow connection of said plug with a mating connector.
